(19) United States
(12) Patent Application Publication
(10) Pub. No.: US 2011/0304995 A1
(43) Pub. Date: Dec. 15, 2011

(54) TELEVISION APPARATUS AND ELECTRONIC DEVICE

(75) Inventors: Wataru NAKANISHI, Ome-shi (JP); Toshikatsu NAKAMURA, Akishima-shi (JP); Daisuke MAEHARA, Ome-shi (JP); Kohei WADA, Tachikawa-shi (JP)

(73) Assignee: KABUSHIKI KAISHA TOSHIBA, Tokyo (JP)

(21) Appl. No.: 13/151,132

(22) Filed: Jun. 1, 2011

(30) Foreign Application Priority Data
Jun. 10, 2010 (JP) 2010-133141

(51) Int. Cl. H05K 1/02; H05K 7/00

(52) U.S. Cl. 361/749; 361/748; 361/760

(57) ABSTRACT

According to one embodiment, a television apparatus includes a flexible printed wiring board on which a screw hole is provided, and a reinforcing plate which is adhered to the flexible printed wiring board and provided with an opening. The television apparatus includes an indication, and the indication is provided on a surface of the printed wiring board adhered to the reinforcing plate at an exposed position in the opening, and indicates a position of the screw hole.

### CROSS-REFERENCE TO RELATED APPLICATIONS

This application is based upon and claims the benefit of priority from Japanese Patent Application No. 2010-133141, filed Jun. 10, 2010; the entire contents of which are incorporated herein by reference.

### FIELD

Embodiments described herein relate generally to a television apparatus and an electronic device provided with a printed wiring board.

### BACKGROUND

In an electronic device, such as a television, a rigid printed wiring board, and a flexible printed wiring board are often used. In the flexible printed wiring board, a pattern of a conductor is arranged on a surface of a base member. The pattern of the conductor is covered with a cover film excluding an input side end portion and an output side end portion.

By bonding a reinforcing plate to such a flexible printed wiring board, the flexible printed wiring board can be improved in strength, and the flexible printed wiring board can be made easy to handle. On the other hand, information, such as characters and symbols, may be added to the flexible printed wiring board. However, if a reinforcing plate is bonded to a flexible printed wiring board as stated above, the information, such as the characters and symbols, cannot be visually identified.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view which shows a television apparatus, which is an example of an electronic device of a first embodiment;

FIG. 2 is an exemplary perspective view which shows an interior of the television apparatus shown in FIG. 1 when it is dismantled;

FIG. 3 is an exemplary plan view which shows a flexible unit of the television apparatus shown in FIG. 2;

FIG. 4 is an exemplary perspective view which shows a portable computer, which is an example of an electronic device of a second embodiment;

FIG. 5 is an exemplary plan view which shows a state where a cover of a second unit of the portable computer shown in FIG. 4 is removed;

FIG. 6 is an exemplary plan view which shows a flexible unit of the portable computer shown in FIG. 5;

FIG. 7 is an exemplary plan view which shows a flexible unit of a portable computer, which is an example of an electronic device of a third embodiment;

FIG. 8 is an exemplary sectional view taken along line F8-F8 shown in FIG. 7;

FIG. 9 is an exemplary plan view which shows a flexible unit of a portable computer, which is an example of an electronic device of a fourth embodiment;

FIG. 10 is an exemplary plan view which shows the periphery of an indication of a flexible printed wiring board shown in FIG. 9 in an enlarged scale;

FIG. 11 is an exemplary plan view which shows a first modification of the indication of the flexible printed wiring board of the fourth embodiment;

FIG. 12 is an exemplary plan view which shows a second modification of the indication of the flexible printed wiring board of the fourth embodiment; and

FIG. 13 shows an exemplary third modification of the indication of the flexible printed wiring board of the fourth embodiment, and is a sectional view taken along a thickness direction of the flexible unit.

### DETAILED DESCRIPTION

Various embodiments will be described hereinafter with reference to the accompanying drawings.

In general, according to one embodiment, a television apparatus includes a flexible printed wiring board on which a screw hole is provided, and a reinforcing plate which is adhered to the flexible printed wiring board and provided with an opening. The television apparatus includes an indication, and the indication is provided on a surface of the printed wiring board adhered to the reinforcing plate at an exposed position in the opening, and indicates a position of the screw hole.

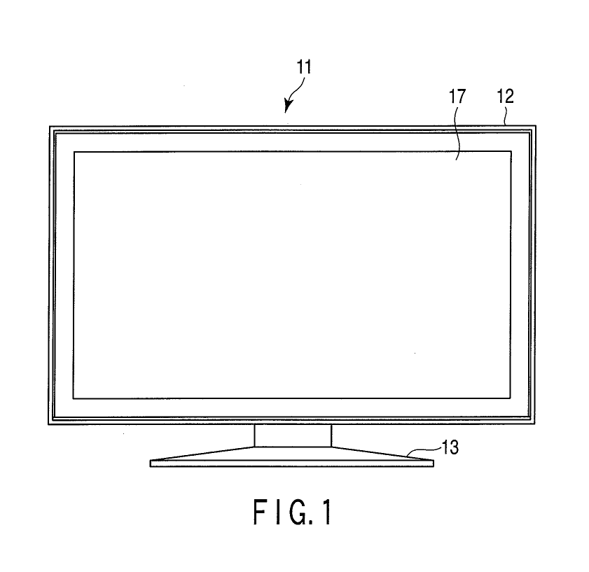

A first embodiment of an electronic device will now be described with reference to FIGS. 1 to 3. As shown in FIG. 1, a television apparatus 11, which is an example of an electronic device according to the present embodiment, is a thin display having a rectangular appearance. The television apparatus 11 comprises a housing 12 and a leg 13 which supports the housing 12.

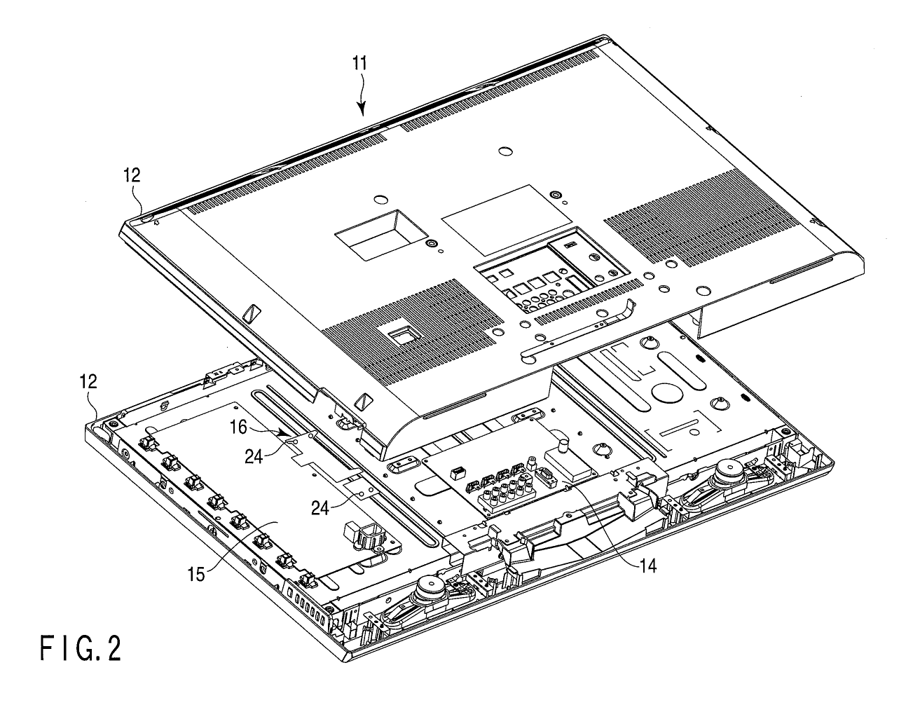

As shown in FIG. 1 and FIG. 2, within the housing 12, the television apparatus 11 comprises a tuner board 14, a printed circuit board 15, which is the so-called system board configured to control each part of the television apparatus 11 in an integrated manner, a flexible unit 16 which is connected to the printed circuit board 15 via a connector, and a flat display panel 17. The display panel 17 is a liquid crystal display panel, for example, but may be other types of display panels, such as a plasma display panel.

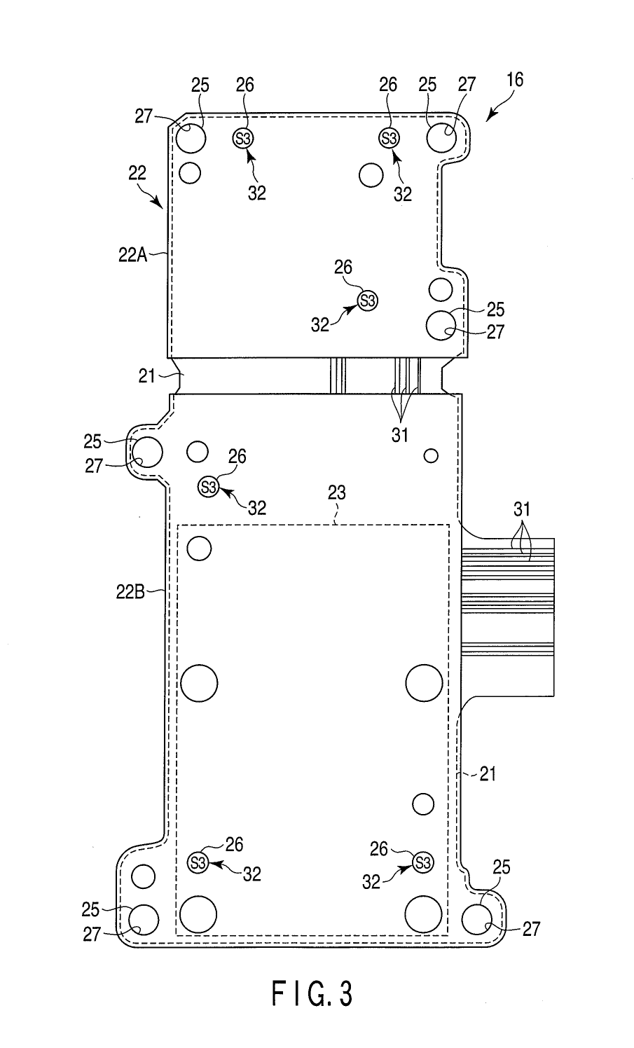

As shown in FIG. 3, the flexible unit 16 has a flexible printed wiring board 21, which is an example of a printed wiring board, a reinforcing plate 22 which is adhered to the flexible printed wiring board 21, a module 23 which is mounted on the flexible printed wiring board 21, and screws 24 which fix the flexible printed wiring board 21 and the reinforcing plate 22 to the display panel 17. In the present embodiment, the module 23 is a wireless LAN module, for example, but is not limited to above. That is, a 3G communication module, for example, may be used. Further, in the present embodiment, although the flexible printed wiring board 21 and the reinforcing plate 22 are fixed to the display panel 17 by a plurality of screws 24, they may be fixed to the housing 12.

The reinforcing plate 22 is adhered to the flexible printed wiring board 21, and thus a certain degree of strength is imparted to the flexible printed wiring board 21 on which the module 23 is mounted. The reinforcing plate 22 has a first section 22A and a second section 22B which are separated from each other, and each of them is adhered to the flexible printed wiring board 21. The first section 22A and the second section 22B are made of glass epoxy resin, and have insulation properties. In each of the first section 22A and the second section 22B, first screw holes 25 in which screws 24 are inserted, and through-holes 26 which are provided near the first screw holes 25 are provided. The through-holes 26 are examples of openings and formed to be circular. The through-holes 26 are arranged at positions corresponding to indications 32 on the flexible printed wiring board 21 which will be described later.

The flexible printed wiring board 21 is formed by stacking a plurality of wiring layers (copper foil) and insulating layers made of polyimide alternately on a base member made of polyimide, for example. However, the structure of the flexible printed wiring board 21 is not limited to above. The flexible printed wiring board 21 may be formed by arranging a wiring layer on both sides of the base member. Alternatively, the flexible printed wiring board 21 may be formed by arranging a wiring layer on only one side of the base member. On the flexible printed wiring board 21, second screw holes 27 in which the screws 24 are inserted are provided. Further, the flexible printed wiring board 21 includes a wiring pattern 31 and indications 32 which indicate the positions of the second screw holes 27 and the types of the screws 24.

The indications 32 are formed by at least one of a character, figure, and symbol, or a combination thereof. In the present embodiment, the indications 32 are displayed on the flexible printed wiring board 21 with characters, such as “S3”. The indications 32 are provided on a surface of the flexible printed wiring board 21 adhered to the reinforcing plate 22 at places near the second screw holes 27. The indications 32 are a conductor pattern made of a copper foil or the like and formed on the base member or the insulating layer. The indications 32 are exposed outside by the through-holes 26, and thus externally visible to a worker via the through-holes 26. Further, the characters “S3” mean that the heads of the screws 24 are flat and the screws 24 having a diameter of 3 mm in the shank should be inserted into the second screw holes 27 near the indications 32 to be fastened.

As the worker inserts the screws 24 into the first screw holes 25 and the second screw holes 27 to be fastened in accordance with the indications 32, the flexible unit 16 can be easily fixed to the display panel 17.

According to the first embodiment, the television apparatus 11 comprises the flexible printed wiring board 21 on which screws holes are provided, the reinforcing plate 22 which is adhered to the flexible printed wiring board 21 and provided with openings, and the indications 32 which are provided on a surface of the flexible printed wiring board 21 adhered to the reinforcing plate 22 at the exposed positions in the openings, and indicate the positions of the screw holes.

By virtue of this structure that the indications 32 are provided on the flexible printed wiring board 21, the worker does not fail to recognize the portions where the screws 24 should be fastened, and the workability is improved. Further, since the indications 32 are provided at the exposed positions in the openings of the reinforcing plate 22, the indications 32 are not hidden by the reinforcing plate 22, and the function of the indications 32 can be exhibited.

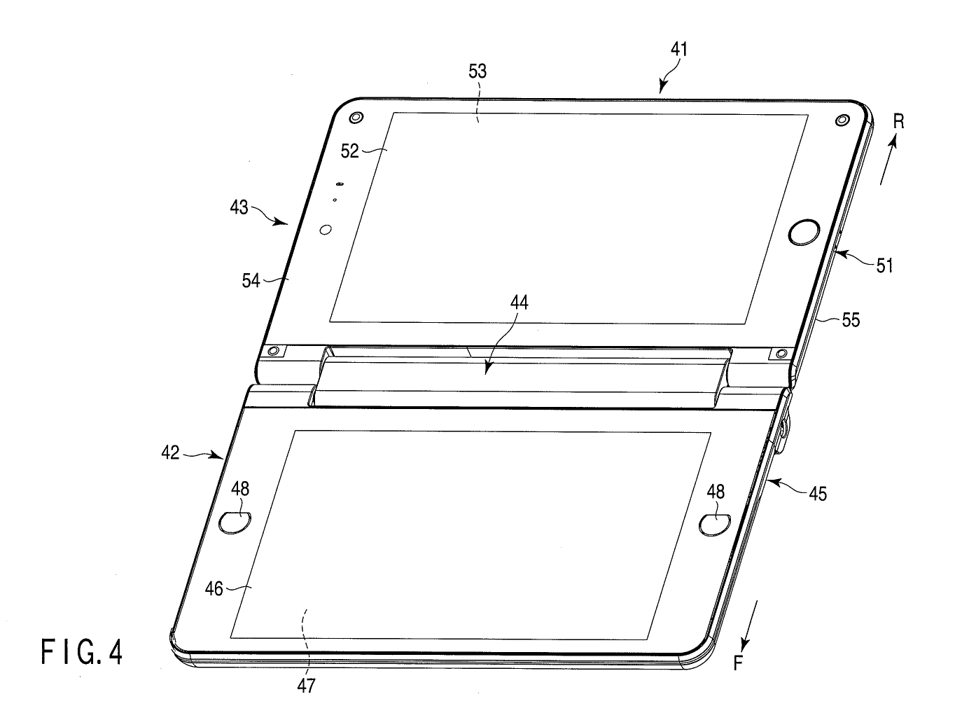

A second embodiment of an electronic device will now be described with reference to FIGS. 4 to 6. A portable computer 41, which is an example of the electronic device of the second embodiment, is different from the television apparatus 11 of the first embodiment in the outside appearance, but mostly the same in the main structure. Accordingly, an explanation will be given mainly for the parts different from the first embodiment, and an explanation will be omitted for the common parts by assigning the same reference numerals thereto. In the embodiment described below, the near side to the user (that is, the user side) will be defined as front F, the far side from the user as rear R, the left-hand side of the user as left, the right-hand side of the user as right, the upper side from the user's position as up and the lower side from the user's position as down.

As shown in FIG. 4, the portable computer 41 comprises a first unit 42 which is positioned in the front of this figure, a second unit 43 which is positioned in the rear of this figure, and a hinge unit 44 which is positioned between the first unit 42 and the second unit 43 and rotatably connects these two units.

The first unit 42 includes a first case 45, a first touch panel 46 which is arranged on the first case 45, and a first display 47 which is provided under the first touch panel 46 inside the first case 45. The first display 47 is a liquid crystal display, for example, and is arranged at a position adjacent to the first touch panel 46. Further, the first unit 42 has a pair of operation buttons 48, which are arranged on the sides of the first unit 42, with the first touch panel 46 located therebetween.

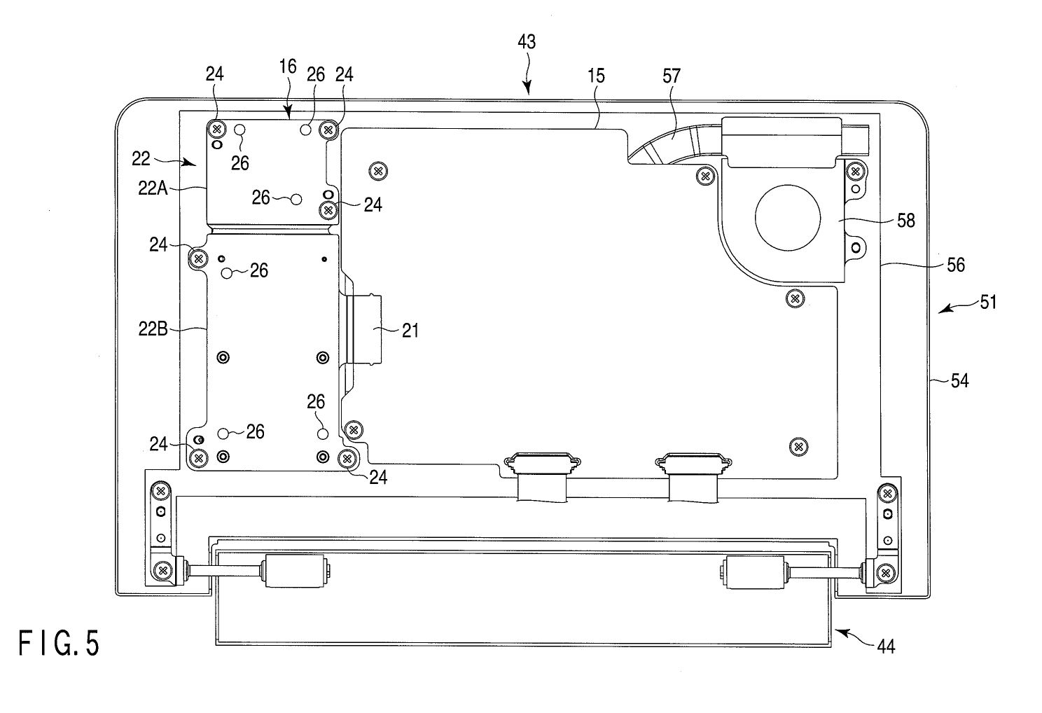

As shown in FIG. 4, the second unit 43 includes a second case 51, a second touch panel 52 which is arranged on the second case 51, and a second display 53 which is provided under the second touch panel 52 inside the second case 51. As shown in FIG. 4 and FIG. 5, the second case 51 includes a mask 54 which covers the front of the second touch panel 52, a cover 55 which covers the back of the second display 53, and an inner frame 56 which is provided between the mask 54 and the cover 55. The cover 55, the mask 54, and the inner frame 56 are fixed to each other by screws, etc. FIG. 5 shows a state where the cover 55 is removed.

As shown in FIG. 5, the second unit 43 further includes a printed circuit board 15, which is a system board on which a CPU or the like is mounted, a flexible unit 16 which is provided independently of the printed circuit board 15, and a heat pipe 57 and a fan unit 58 for promoting cooling of the CPU or the like.

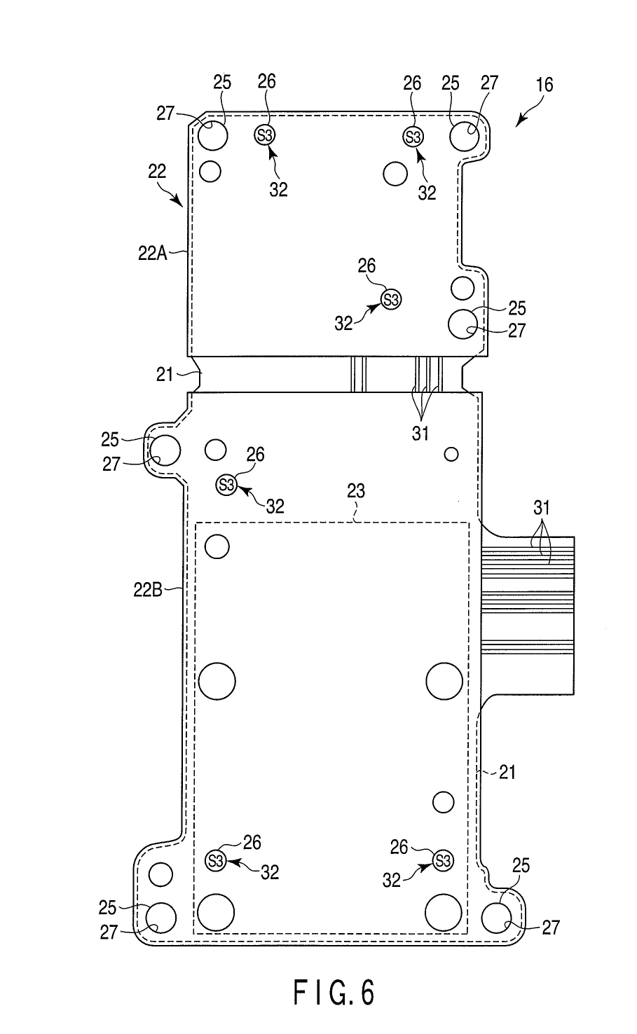

As shown in FIG. 5 and FIG. 6, the flexible unit 16 includes a flexible printed wiring board 21, which is an example of a printed wiring board, a reinforcing plate 22 which is adhered to the flexible printed wiring board 21, a module 23 which is mounted on the flexible printed wiring board 21, and screws 24 which fix the flexible printed wiring board 21 and the reinforcing plate 22 to the inner frame 56. In the present embodiment, the module 23 is a wireless LAN module, for example, but is not limited to above. That is, other modules, such as a 3G communication module, may be used.

As shown in FIG. 6, the reinforcing plate 22 has a first section 22A and a second section 22B which are adhered to the flexible printed wiring board 21. The first section 22A and the second section 22B are made of glass epoxy resin. In the first section 22A and the second section 22B of the reinforcing plate 22, first screw holes 25 in which screws 24 are inserted, and through-holes 26 which are provided near the first screw holes 25 are provided. The through-holes 26 are examples of openings and formed to be circular. The through-holes 26 are arranged at positions corresponding to indications 32 on the flexible printed wiring board 21 which will be described later.

The flexible printed wiring board 21 is formed by stacking a plurality of wiring layers and insulating layers made of polyimide alternately on a base member made of polyimide, for example. The flexible printed wiring board 21 may be formed by arranging a wiring layer on both sides of the base member. Alternatively, the flexible printed wiring board 21 may be formed by arranging a wiring layer on only one side of the base member. On the flexible printed wiring board 21, second screw holes 27 in which the screws 24 are inserted are provided. Further, the flexible printed wiring board 21 includes a wiring pattern 31 and indications 32 which indicate the positions of the second screw holes 27 and the types of the screws 24.

The indications 32 are formed by at least one of a character, figure, and symbol, or a combination thereof. In the present embodiment, the indications 32 are displayed on the flexible printed wiring board 21 with characters, such as “S3”. The indications 32 are provided on a surface of the flexible printed wiring board 21 adhered to the reinforcing plate 22 at places near the second screw holes 27. The indications 32 are a conductor pattern made of copper or the like and formed on the base member or the insulating layer. The indications 32 are exposed outside by the through-holes 26, and thus externally visible via the through-holes 26 of the reinforcing plate 22.

According to the second embodiment, the portable computer 41 comprises a printed wiring board on which screw holes are provided, the reinforcing plate 22 which is adhered to the printed wiring board and provided with openings, and the indications 32 which are provided on a surface of the printed wiring board adhered to the reinforcing plate 22 at the exposed positions in the openings, and indicate the positions of the screw holes. By virtue of this structure that the indications 32 are provided on the flexible printed wiring board 21, a worker does not fail to recognize the portions where the screws 24 should be fastened, and the workability during assembly is improved. Further, since the indications 32 are provided at the exposed positions in the openings of the reinforcing plate 22, the indications 32 are not hidden by the reinforcing plate 22, and the function of the indications 32 can be exhibited. In addition, recently, there are cases where a translucent reinforcing plate cannot be used in an electronic device in order to meet the standards of halogen-free or the like. In such a case, the present embodiment is particularly useful.

In this case, the indications 32 are a conductor pattern formed on a printed wiring board. With this structure, indications can be formed by the conductor pattern collectively in forming a wiring pattern 31. That is, a separate step of serigraph, etc., is not required for arranging the indications 32. Accordingly, a manufacturing process is not complicated, and productivity can be improved.

The indications 32 indicate the types of screws 24 which are inserted in screw holes. Accordingly, the worker will not misunderstand the type of screws 24 to be inserted in the screw holes to be fastened, and the workability can be further improved.

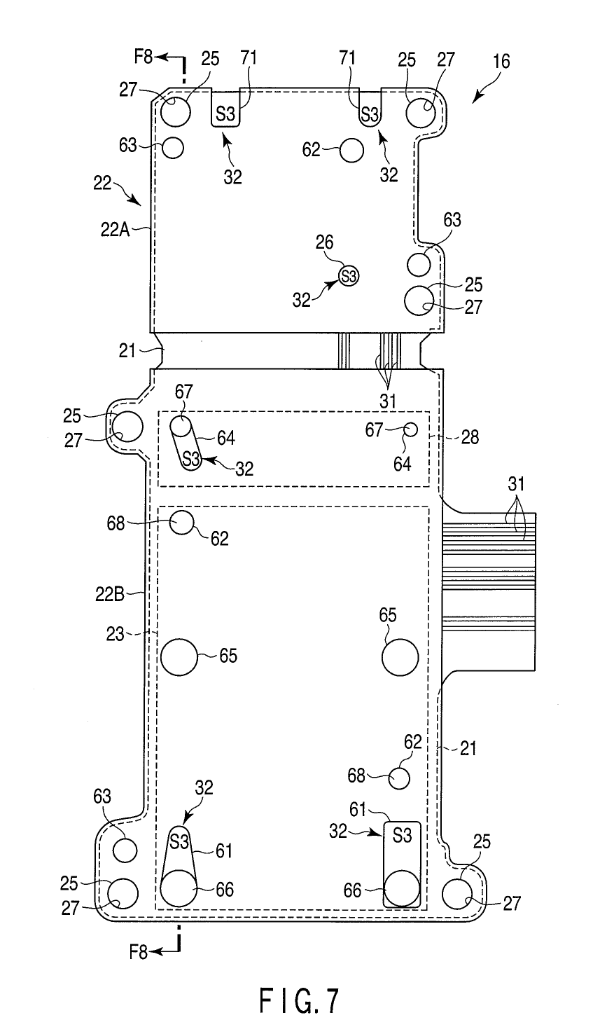

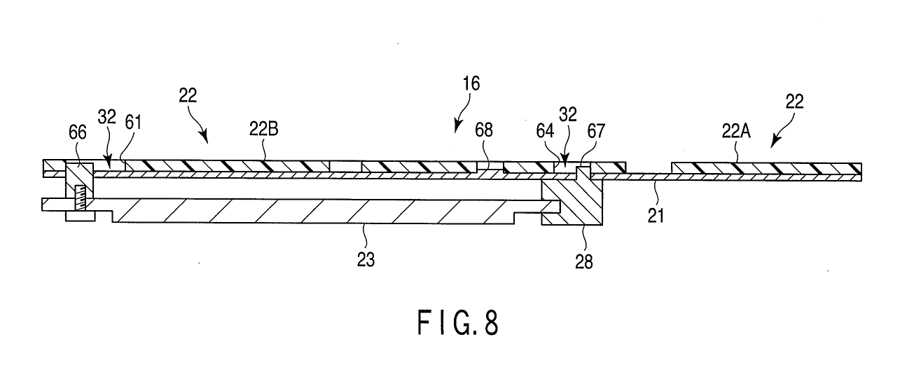

A third embodiment of an electronic device will now be described with reference to FIG. 7 and FIG. 8. A portable computer 41, which is an example of the electronic device of the third embodiment, is different from that of the second embodiment in the appearance of through-holes 26. However, the other parts are in common with the parts of the second embodiment. Accordingly, an explanation will be given mainly for the parts different from the second embodiment, and an explanation will be omitted for the common parts by assigning the same reference numerals thereto. The portable computer 41 of the third embodiment has the same appearance as the portable computer 41 of the second embodiment shown in FIG. 4.

As shown in FIG. 7, a flexible unit 16 includes a flexible printed wiring board 21, a reinforcing plate 22 which is adhered to the flexible printed wiring board 21, a module 23 which is mounted on the flexible printed wiring board 21, and screws 24 which fix the flexible printed wiring board 21 and the reinforcing plate 22 to an inner frame 56. In the present embodiment, the module 23 is a wireless LAN module, for example.

The reinforcing plate 22 has a first section 22A and a second section 22B which are adhered to the flexible printed wiring board 21. The first section 22A and the second section 22B are made of glass epoxy resin. In the first section 22A and the second section 22B, first screw holes 25 in which the screws 24 are inserted, first through-holes 61 which are provided near the first screw holes 25, second through-holes 62 configured to position the flexible printed wiring board 21 and the reinforcing plate 22, third through-holes 63 in which pins configured to position the flexible printed wiring board 21 and the reinforcing plate 22 with respect to the inner frame 56 are inserted, fourth through-holes 64 configured to position and fix a connector 28, and fifth through-holes 65 configured to fix other module having a size different from the module 23, are provided.

The first through-holes 61 are examples of openings, and formed to be oval or rectangular. The first through-holes 61 are formed to be larger than the through-holes 26 of the second embodiment. As shown in FIG. 8, in each of the first through-holes 61, a stud 66 which is configured to fix the module 23 is provided. Further, in each of the fourth through-holes 64, a projected pin 67 which is integral with the connector 28 is provided. As shown in FIG. 7, the first though-holes 61 and the fourth-through holes 64 are arranged at positions corresponding to indications 32 on the flexible printed wiring board 21 which will be described later. As shown in FIGS. 7 and 8, convex portions 68 which are projected from the flexible printed wiring board 21, for example, fit into the second through-holes 62, thereby positioning the flexible printed wiring board 21 and the reinforcing plate 22.

As shown in FIG. 7 the reinforcing plate 22 is provided with cutout sections 71 to allow the indications 32 on the flexible printed wiring board 21 which will be described later to be exposed outside. The cutout sections 71 are examples of openings and can be formed into various shapes, such as rectangular and oval.

In the flexible printed wiring board 21, second screw holes 27 in which the screws 24 are inserted are provided. Further, the flexible printed wiring board 21 includes a wiring pattern 31, and indications 32 which indicate the positions where the screws 24 should be fastened and the types of the screws 24. In the present embodiment, the indications 32 are displayed on the flexible printed wiring board 21 with characters, such as “S3”. The indications 32 are a conductor pattern made of copper or the like and formed on a base member or an insulating layer. The indications 32 are provided near the second screw holes 27. The indications 32 are exposed outside by the first through-holes 61 and the fourth through-holes 64, and are visible from the outside via the first through-holes 61 and the fourth through-holes 64.

According to the third embodiment, the portable computer 41 further comprises the module 23 mounted on a printed wiring board, and the openings are through-holes. In each of the openings, the stud 66 for fixing the module 23 is provided. In this structure, a hole for inserting the stud 66 can serve as a through-hole for allowing the indications 32 to be exposed outside. Accordingly, as compared to the case of providing a hole for inserting the stud 66 and a through-hole for allowing one of the indications 32 to be exposed outside separately, a structure can be simplified.

Some of the openings are structured by the cutout sections 71. Even in such a structure, the indications 32 can be prevented from being hidden by the reinforcing plate 22, and the function of the indications 32 can be exhibited.

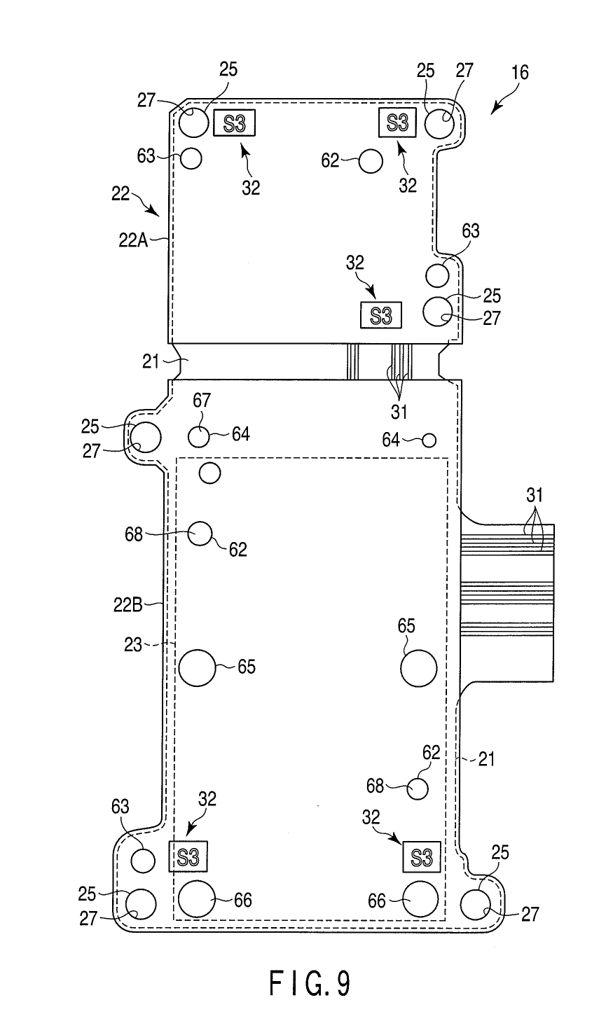

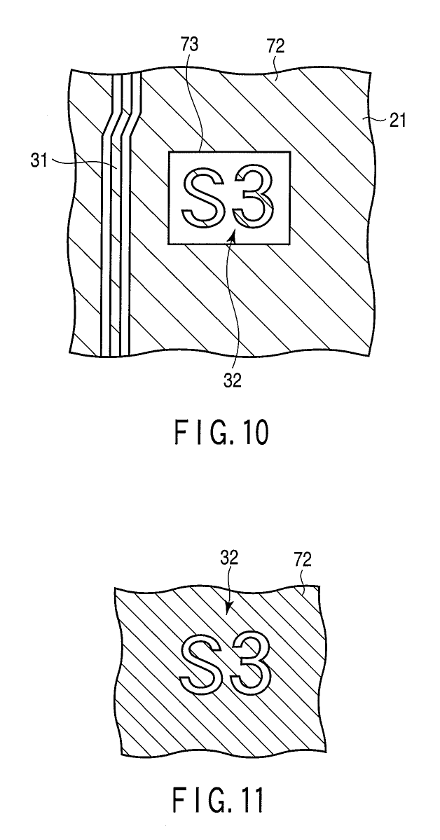

A fourth embodiment of an electronic device will now be described with reference to FIGS. 9 and 10. A portable computer 41, which is an example of the electronic device of the fourth embodiment is different from that of the third embodiment in that the quality of a reinforcing plate 22 is different and first through-holes 61 are not provided on the reinforcing plate 22. However, the other parts are in common with the parts of the third embodiment. Accordingly, an explanation will be given mainly for the parts different from the third embodiment, and an explanation will be omitted for the common parts by assigning the same reference numerals thereto. The portable computer 41 of the fourth embodiment has the same appearance as the portable computer 41 of the second embodiment shown in FIG. 4.

As shown in FIG. 9, a flexible unit 16 includes a flexible printed wiring board 21, a reinforcing plate 22 adhered to the flexible printed wiring board 21, a module 23 mounted on the flexible printed wiring board 21, and screws 24 for fixing the flexible printed wiring board 21 and the reinforcing plate 22 to an inner frame 56. In the present embodiment, the module 23 is a wireless LAN module, for example.

The reinforcing plate 22 includes a first section 22A and a second section 22B which are adhered to the flexible printed wiring board 21. Each of the first section 22A and the second section 22B is structured by a translucent resin plate. Here, the “translucent resin plate” includes a transparent resin plate and a semitransparent resin plate. In the present embodiment, the first section 22A and the second section 22B are formed of polycarbonate, for example. However, the material is not limited to above, and may be any type of material, such as acrylic and vinyl chloride, as long as it has translucency.

In the first section 22A and the second section 22B of the reinforcing plate 22, first screw holes 25 in which the screws 24 are inserted, second through-holes 62 configured to position the flexible printed wiring board 21 and the reinforcing plate 22, third through-holes 63 configured to position the flexible printed wiring board 21 and the reinforcing plate 22 with respect to the inner frame 56, and fifth through-holes 65 configured to fix other module having a size different from the module 23, are provided.

In the flexible printed wiring board 21, second screw holes 27 in which the screws 24 are inserted are provided. Further, the flexible printed wiring board 21 includes a wiring pattern 31, and indications 32 which indicate the positions where the screws 24 should be fastened and the types of the screws 24. In the present embodiment, the indications 32 are displayed on the flexible printed wiring board 21 with characters, such as “S3”. The indications 32 are a conductor pattern made of copper or the like and formed on a base member or an insulating layer. The indications 32 are provided near the second screw holes 27. The indications 32 are visible from the outside via the translucent reinforcing plate 22.

For example, the indication 32 shown in FIG. 10 is formed by providing an outline section 73 in an unetched copper 72 (solid pattern 72), which is formed by applying a copper foil on the entire surface of a base member or an insulating layer, and by forming a conductor pattern in the outline section 73. Further, in the present embodiment, while the indication 32 is formed by the conductor pattern in the outline section 73, it may be formed with characters, figures and symbols, etc., directly on the unetched copper 72 as shown in FIG. 11 (like outline characters on a colored background).

According to the fourth embodiment, the portable computer 41 comprises a printed wiring board in which screw holes are provided, the reinforcing plate 22 which is adhered to the printed wiring board and has translucency, and the indications 32 which are provided on a surface of the printed wiring board adhered to the reinforcing plate and indicate the positions of the screw holes.

With this structure, since the reinforcing plate 22 has translucency, a through-hole 26 does not need to be provided on the reinforcing plate 22. Thus, in addition to preventing the strength of the reinforcing plate 22 from being lowered, the structure of the reinforcing plate 22 can be simplified. In addition, the indications 32 are a conductor pattern formed on the printed wiring board. For this reason, the wiring pattern 31 and the indications 32 can be formed collectively by the conductor pattern. Thus, a manufacturing process is not complicated, and productivity can be improved.

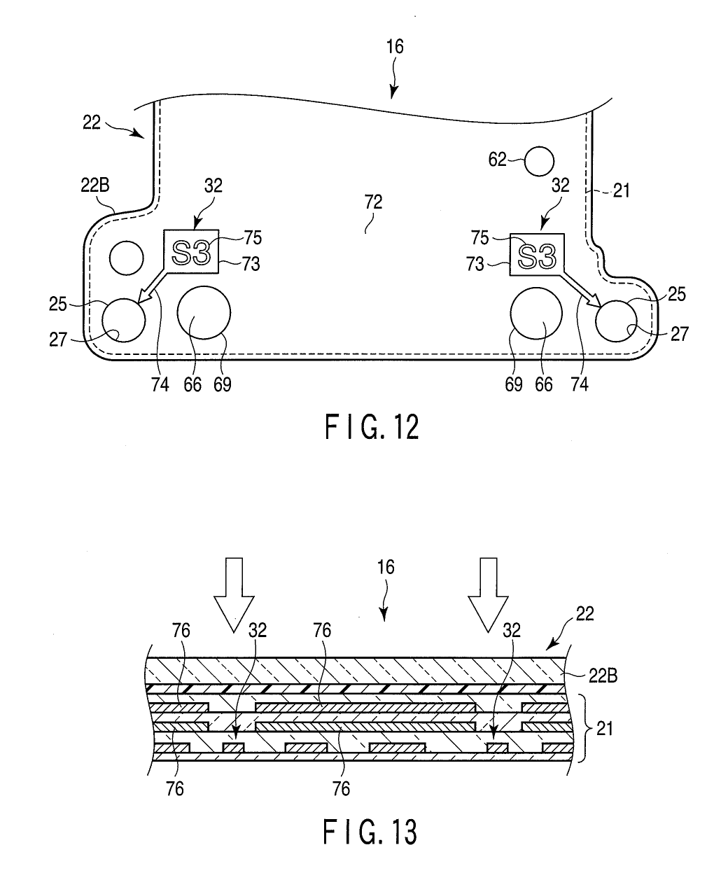

Next, a modification of the fourth embodiment will be described with reference to FIG. 12 and FIG. 13. As shown in FIG. 12, in this modification, each of indications 32 is formed by a combination of an outline arrow 74 arranged on an unetched copper 72 and characters 75 (“S3”) formed as a conductor pattern in an outline section 73. According to this modification, even if several kinds of through-holes 62 and 69 are to be provided on a reinforcing plate 22, a worker does not fail to recognize the positions of second screw holes 27, and the workability is improved.

In each of the above embodiments, indications are provided at positions close to the uppermost layer of the flexible printed wiring board 21, for example. However, as shown in FIG. 13, the indications 32 can be provided in a layer inside the flexible printed wiring board 21. In this case, as shown in FIG. 13, preferably, a layer closer to the surface than the indications 32 are should have translucency, and visibility of the indications 32 should be secured by not providing conductor pattern 76 at positions which overlap the indications 32. This structure enables the worker to visually identify the indications 32 from the direction shown by arrows in FIG. 13. Further, the “surface of the flexible printed wiring board adhered to the reinforcing plate” is intended to include inner layers of the flexible printed wiring board 21, as in this modification.

The electronic devices are not limited to the television apparatus 11 and the portable computers 41 of the above embodiments, and may be embodied as other types of electronic devices, such as a cellular phone, needless to say. Further, in each of the above embodiments, while the case of using a flexible printed wiring board has been described as an example, each of the structures of the above embodiments can be applied to the so-called rigid board having rigidity.

In each of the above embodiments, the conductor pattern forming the indications is provided separately from the wiring pattern 31 forming the wiring. However, the indications 32 may be formed by the wiring pattern 31. Further, while the indications 32 indicate the positions of the second screw holes 27 and the types of the screws 24, the function is not limited to this. For example, the indications 32 may represent the names of makers or other corporate logotypes. Alternatively, the indications 32 may be just arrows indicating the positions of the second screw holes 27. Further, in each of the above embodiments, while the indications 32 are formed by a conductor pattern, indications may be formed by performing serigraph or applying stamps, etc., on the flexible printed wiring board 21 or the reinforcing plate 22.

The electronic device described in the present specification is not limited to be above embodiments, and may be embodied by modifying constituent features without departing from the spirit when the electronic device is put into practice. Further, various inventions can be achieved by suitably combining the constituent features disclosed in the above embodiments. For example, some constituent features may be deleted from the entire constituent features shown in the embodiments. Further, constituent features of different embodiments may be combined suitably.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a flexible printed wiring board comprising a screw hole;
a reinforcing plate attached to the flexible printed wiring board and comprising an opening; and
an indicator disposed on a surface of the flexible printed wiring board at an exposed position in the opening, wherein the indicator is configured to indicate a position of the screw hole.

2. An electronic device comprising:
a printed wiring board comprising a screw hole;
a reinforcing plate attached to the printed wiring board and comprising an opening; and
an indicator disposed on a surface of the printed wiring board at an exposed position in the opening, wherein the indicator is configured to indicate a position of the screw hole.

3. The electronic device of claim 2, wherein the indicator comprises a conductor pattern.

4. The electronic device of claim 3, wherein the indicator is configured to indicate a type of screw that the screw hole is capable of receiving.

5. The electronic device of claim 4, wherein the opening comprises a through-hole, and further comprising
a module disposed on the printed wiring board, and
a stud, provided in the opening, configured to mount the module to the printed wiring board.

6. The electronic device of claim 4, wherein the opening comprises a cutout section.

7. The electronic device of claim 5, wherein the indicator is disposed near the screw hole.

8. An electronic device comprising:
a printed wiring board on which a screw hole is disposed;
a translucent reinforcing plate attached to the printed wiring board; and
an indicator disposed on a surface of the printed wiring board, wherein the indicator is configured to indicate a position of the screw hole.

9. The electronic device of claim 8, wherein the indicator comprises a conductor pattern.

10. The electronic device of claim 9, wherein the indicator is configured to indicate a type of screw that the screw hole is capable of receiving.

11. The electronic device of claim 10, wherein the indicator is disposed near the screw hole.
